(19) United States
(12) Patent Application Publication
(10) Pub. No.: US 2012/0306095 A1
(43) Pub. Date: Dec. 6, 2012

(54) SEMICONDUCTOR PACKAGE AND FABRICATION METHOD OF THE SAME

(75) Inventor: KyuJin HAN, Yongin-si (KR)

(73) Assignee: Samsung Electronics Co., Ltd, Suwon-si (KR)

(21) Appl. No.: 13/482,570

(22) Filed: May 29, 2012

(30) Foreign Application Priority Data
May 30, 2011 (KR) 10-2011-0051545

(51) Int. Cl. H01L 23/52

(52) U.S. Cl. 257/774; 257/E23.011

(57) ABSTRACT

A semiconductor package and a fabrication method are provided. The semiconductor package includes a first substrate including opposite first and second surfaces, a first through electrode penetrating the first substrate, a second substrate including opposite third and fourth surfaces, a second through electrode penetrating the second substrate, an insulating pattern interposed between the second surface of the first substrate and the third surface of the second substrate to at least partially expose the second surface of the first substrate and the third surface of the second substrate, and a connecting pattern disposed in a space defined by the insulating pattern and the first and second substrates to electrically connect the first through electrode with the second through electrode.

### CROSS-REFERENCE TO RELATED APPLICATIONS

This U.S. non-provisional patent application claims priority under 35 U.S.C. §119 to Korean Patent Application No. 10-2011-0051545, filed on May 30, 2011, in the Korean Intellectual Property Office, the entire contents of which are hereby incorporated by reference.

### BACKGROUND OF THE INVENTION

1. Field of the Invention

Embodiments of the present general inventive concepts relate generally to a semiconductor package and a method of fabricating the same. More particularly, embodiments of the present general inventive concepts relate to a semiconductor package with a through electrode and a method of fabricating the same.

2. Description of the Related Art

Electronic circuits and interconnection lines are disposed in or on a semiconductor package and a package substrate. The semiconductor package and the package substrates may be electrically connected to each other by using the through-silicon via (TSV) penetrating the semiconductor package and the package substrate. In the case that multi-layered substrates are stacked in the semiconductor package, the multi-layered substrates may be electrically connected to each other by using the TSV.

### SUMMARY OF THE INVENTION

Embodiments of the inventive concepts provide a semiconductor package, in which substrates with through electrodes therein are electrically connected to each other.

Other embodiments of the inventive concepts provide a method of connecting substrates with through electrodes with each other.

Additional features and utilities of the present general inventive concept will be set forth in part in the description which follows and, in part, will be obvious from the description, or may be learned by practice of the present general inventive concept.

According to example embodiments of the present general inventive concepts, a semiconductor package may include a first substrate including a first surface and a second surface facing each other, a first through electrode penetrating the first substrate, a second substrate including a third surface and a fourth surface facing each other, a second through electrode penetrating the second substrate, an insulating pattern interposed between the second surface of the first substrate and the third surface of the second substrate to at least partially expose the second surface of the first substrate and the third surface of the second substrate, and a connecting pattern disposed in a space defined by the insulating pattern and the first and second substrates to electrically connect the first through electrode with the second through electrode.

In some embodiments, the package may further include a first metal pad disposed on the third surface of the second substrate and adjacent to the second through electrode. The first and second through electrodes may be electrically connected to each other via the first metal pad.

In other embodiments, the package may further include a second metal pad disposed on the second surface of the first substrate and adjacent to the first through electrode. The first and second through electrodes may be electrically connected to each other via the second metal pad.

In still other embodiments, the package may further include a first interlayer dielectric on the second surface of the first substrate, and a second interlayer dielectric on the first interlayer dielectric. The first through electrode may penetrate the first interlayer dielectric in such a way that a top surface of the first through electrode may be at least coplanar with a bottom surface of the second interlayer dielectric.

In even other embodiments, the package may further include a metal interconnection line disposed in the second interlayer dielectric to electrically connect the connecting pattern with the first through electrode.

In yet other embodiments, the package may further include an adhesive layer on the second surface of the first substrate.

In further embodiments, the package may further include an insulating layer on at least one of the third surface of the second substrate or the second surface of the first substrate.

In still further embodiments, the connecting pattern may fill at least a portion of the space defined by the insulating pattern and the first and second substrates.

In yet further embodiments, the package may further include a package substrate disposed to face the first surface of the first substrate, a conductive pattern disposed on one surface of the package substrate, and connecting terminals disposed on the other surface of the package substrate.

In yet further embodiments, the connecting pattern and the connecting terminals may be formed of the same material.

Exemplary embodiments of the present general inventive concept also provide a semiconductor package, comprising: a first substrate having a first through electrode penetrating opposing first and second surfaces of the first substrate; a second substrate having a second through electrode penetrating opposing third and fourth surfaces of the second substrate; an insulating pattern located between the second surface of the first substrate and the third surface of the second substrate, exposing at least part of the second surface of the first substrate and at least part of the third surface of the second substrate; and\an electrically connecting pattern in a space defined by the first substrate, the second substrate and the insulating pattern.

According to other example embodiments of the inventive concepts, a method of fabricating a semiconductor package may include forming a first substrate provided with a first through electrode, the first substrate including first and second surfaces facing each other, the first through electrode penetrating the first substrate, forming a second substrate provided with a second through electrode, the second substrate including third and fourth surfaces facing each other, the second through electrode penetrating the second substrate, forming an insulating pattern between the first and second substrates to expose a portion of the second surface of the first substrate and a portion of the third surface of the second substrate, forming a solder bump in a space defined by the insulating pattern, the first substrate, and the second substrate, and performing a thermal treatment at a temperature higher than a melting point of the solder bump to form a connecting pattern, the connecting pattern filling at least a portion of the space and being electrically connected to the first and second through electrodes.

In some embodiments, the method may further include forming a first metal pad disposed on the first surface of the first substrate and adjacent to the first through electrode.

In other embodiments, the method may further include forming a second metal pad disposed on the second surface of the first substrate and adjacent to the first through electrode.

In yet other embodiments, the method may further include forming an adhesive layer on the second surface of the first substrate to expose a portion of the first metal pad or a portion of the second metal pad.

In further embodiments, the forming of the insulating pattern may be performed to partially expose the first and second through electrodes.

In yet other embodiments, the forming of the solder bump may be performed in such a way that the solder bump has a volume smaller than the space.

In further embodiments, the method may further include forming an insulating layer on the first/third and second/fourth surfaces of at least one of the first and second substrates.

Exemplary embodiments of the present general inventive concept also provide a method of fabricating a semiconductor package, comprising: forming a first substrate having a first through electrode penetrating opposing first and second surfaces of the first substrate; forming a second substrate having a second through electrode penetrating opposing third and fourth surfaces of the second substrate; forming an insulating pattern located between the second surface of the first substrate and the third surface of the second substrate to expose at least part of the second surface of the first substrate and at least part of the third surface of the second substrate; and forming an electrically connecting pattern in a space defined by the first substrate, the second substrate and the insulating pattern.

### BRIEF DESCRIPTION OF THE DRAWINGS

These and/or other features and advantages of the present general inventive concept will become apparent and more readily appreciated from the following description of the embodiments, taken in conjunction with the accompanying drawings of which:

FIGS. 1A and 1B are sectional views of illustrations of a semiconductor package according to example embodiments of the inventive concepts;

FIG. 2 is a sectional view of an illustration of a semiconductor package according to other example embodiments of the inventive concepts;

FIGS. 3 through 5 are sectional views illustrating a method of fabricating a semiconductor package according to example embodiments of the inventive concepts;

FIG. 6 is a sectional view illustrating a semiconductor package and a method of fabricating the same according to further example embodiments of the inventive concepts;

FIG. 7 is a sectional view illustrating a semiconductor package and a method of fabricating the same according to other example embodiments of the inventive concepts;

FIG. 8 is a sectional view illustrating a semiconductor package and a method of fabricating the same according to further example embodiments of the inventive concepts;

FIG. 9 is a sectional view illustrating a method of fabricating a semiconductor package according to other example embodiments of the inventive concepts;

FIG. 10 is a sectional view illustrating a method of fabricating a semiconductor package module according to example embodiments of the inventive concepts;

FIG. 11 is a schematic diagram of a semiconductor package module according to example embodiments of the inventive concepts.

FIG. 12 is a schematic diagram illustrating a memory card according to example embodiments of the inventive concepts;

FIG. 13 is a block diagram illustrating an electronic system according to example embodiments of the inventive concepts; and

FIG. 14 shows an illustration of a mobile phone exemplified as an electronic system according to example embodiments of the inventive concepts.

It should be noted that these figures are intended to illustrate the general characteristics of methods, structure and/or materials utilized in certain example embodiments of the present general inventive concept and to supplement the written description provided below. These drawings are not, however, to scale and may not precisely reflect the precise structural or performance characteristics of any given embodiment, and should not be interpreted as defining or limiting the range of values or properties encompassed by example embodiments of the present general inventive concept. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF THE PREFERRED EMBODIMENTS

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the present general inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

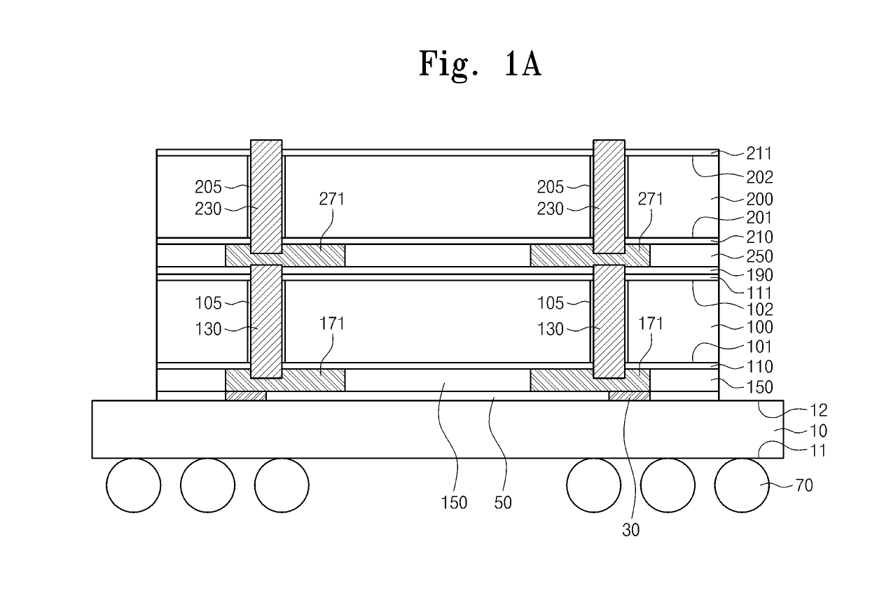

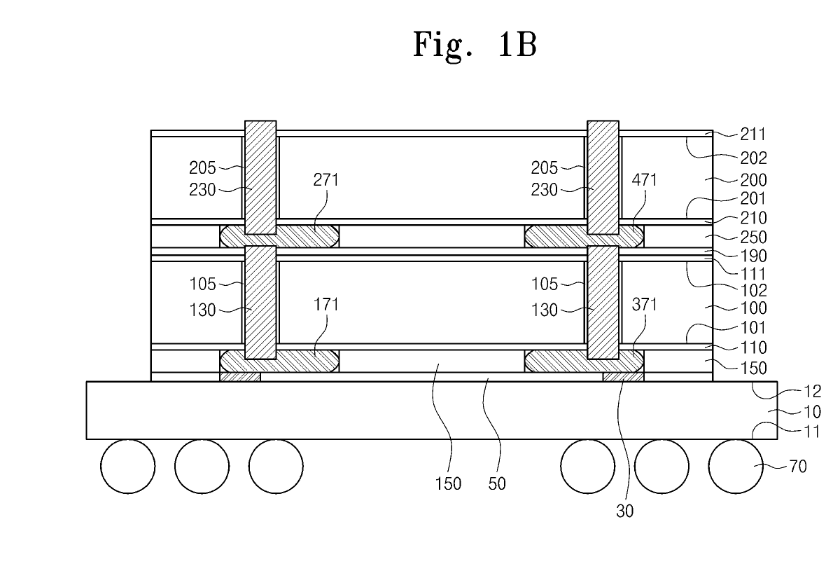

FIGS. 1A and 1B are sectional views of a semiconductor package according to example embodiments of the inventive concepts.

Referring to FIG. 1A, a semiconductor package may include a package substrate 10 with a first surface 11 and a second surface 12 facing each other. The package substrate 10 may include a conductive layer and/or an insulating layer. For example, the package substrate 10 may be a printed circuit board. The package substrate 10 may include an integrated circuit and/or a metal interconnection line, which may be disposed in package substrate 10.

A conductive pattern 30 may be provided on the second surface 12 of the package substrate 10. The conductive pattern 30 may be electrically connected to the integrated circuit and/or the metal interconnection line provided in the package substrate 10. A connecting terminal 70 may be provided on the first surface 11 of the package substrate 10. The connecting terminal 70 may be electrically connected to the integrated circuit and/or the metal interconnection line provided in the package substrate 10. The connecting terminal 70 may be configured to have a ball shape. For example, the connecting terminal 70 may be a solder ball.

A first substrate 100 may be provided on the second surface 12 of the package substrate 10. The first substrate 100 may include a first surface 101 and a second surface 102 facing each other. The first substrate 100 may be formed of silicon (Si) or a semiconductor material containing silicon. The first substrate 100 may include an integrated circuit and/or a metal interconnection line. The integrated circuit may include at least one of a random access memory (RAM) cell, a nonvolatile memory cell, a memory controller, an application processing circuit, a power supply circuit, a modem, or a radio frequency (RF) circuit.

A first and a second insulating layer 110, 111 may be formed on the first and second surfaces 101 and 102 of the first substrate 100. The first and the second insulating layers 110, 111 may be formed of a silicon oxide layer or a silicon nitride layer. A first through electrode 130 may be formed in the first substrate 100 to penetrate the first substrate 100 and the first insulating layer 110. The first through electrode 130 may include at least one of polysilicon, metal, or any combination thereof. For example, the first through electrode 130 may be formed of a metal containing at least one of copper (Cu) or tungsten (W). A first liner layer 105 may be interposed between the first through electrode 130 and the first substrate 100. The first liner layer 105 may be formed of a silicon oxide layer or a silicon nitride layer. In some embodiments, the first through electrode 130 may be configured in such a way that both ends thereof are protruded from the first and second surfaces 101 and 102 of the first substrate 100, respectively. In other words, a vertical length of the first through electrode 130 may be greater than a thickness of the first substrate 100.

A first insulating pattern 150 may be interposed between the package substrate 10 and the first substrate 100. The first insulating pattern 150 may be formed to partially expose the package substrate 10 and the first substrate 100. Furthermore, the first insulating pattern 150 may be formed to expose a portion of the first through electrode 130 and at least a portion of the conductive pattern 30 of the package substrate 10. The first insulating pattern 150 may be formed of photosensitive polyimide (PSPI). A first adhesive layer 50 may be interposed between the package substrate 10 and the first insulating pattern 150. The first adhesive layer 50 may include at least one of insulating materials, such as an epoxy resin, a polyimide, or a permanent photoresist material.

The first adhesive layer 50 may be formed to expose at least a portion of the conductive pattern 30. A first connecting pattern 171 may be provided in a space defined by the package substrate 10, the first substrate 100, and the first insulating pattern 150. The first connecting pattern 171 may be formed of a metal layer. The first connecting pattern 171 may be configured to electrically connect the first through electrode 130 with the conductive pattern 30. In other embodiments, as shown in FIG. 1B, the space may not be fully filled with a third connecting pattern 371, and therefore, there may be a void between the third connecting pattern 371 and the elements defining the space. In other words, the third connecting pattern 371 may have a volume smaller than that of the space defined by the package substrate 10, the first substrate 100, and the first insulating pattern 150.

A second substrate 200 may be provided on the second surface 102 of the first substrate 100. The second substrate 200 may include a third surface 201 and a fourth surface 202 facing each other. The second substrate 200 may be configured in such a way that the third surface 201 thereof faces the second surface 102 of the first substrate 100. A second insulating layer 210, 211 may be provided on the third surface and fourth surface 201 and 202 of the second substrate 200. In some embodiments, the second substrate 200 may be configured to have substantially the same configuration and structure as the first substrate 100. For instance, a second through electrode 230 may be provided in the second substrate 200 to penetrate the second substrate 200 and the second insulating layers 210, 211. The second through electrode 230 may include at least one of polysilicon, metal, or any combination thereof. For example, the second through electrode 230 may be formed of a metal containing at least one of copper (Cu) or tungsten (W). Additionally, a second liner layer 205 may be interposed between the second through electrode 230 and the second substrate 200. The second liner layer 205 may be formed of a silicon oxide layer or a silicon nitride layer. In some embodiments, the second through electrode 230 may be configured in such a way that both ends thereof are protruded from the third and fourth surfaces 201 and 202 of the second substrate 200, respectively. In other words, a vertical length of the second through electrode 230 may be greater than a thickness of the second substrate 200.

A second insulating pattern 250 may be interposed between the first substrate 100 and the second substrate 200. The second insulating pattern 250 may be formed to expose a portion of the second surface 102 of the first substrate 100 and a portion of the third surface 201 of the second substrate 200. Furthermore, the second insulating pattern 250 may be formed to expose a portion of the first through electrode 130 and at least a portion of the second through electrode 230. The second insulating pattern 250 may be formed of photosensitive polyimide (PSPI). A second adhesive layer 190 may be interposed between the second surface 102 of the first substrate 100 and the second insulating pattern 250. The second adhesive layer 190 may include at least one of insulating materials, such as an epoxy resin, a polyimide, or a permanent photoresist material. The second adhesive layer 190 may be formed to expose at least a portion of the first through electrode 130.

A second connecting pattern 271 may be provided in a space defined by the first substrate 100, the second substrate 200, and the second insulating pattern 250. The second connecting pattern 271 may be configured to electrically connect the first through electrode 130 with the second through electrode 230. In other embodiments, as shown in FIG. 1B, the space may not be fully filled with a fourth connecting pattern 471, and therefore, there may be a void between the fourth connecting pattern 471 and the elements defining the space. In other words, the fourth connecting pattern 471 may have a volume smaller than that of the space defined by the first substrate 100, the second substrate 200, and the second insulating pattern 250.

In the semiconductor package, the first insulating pattern 150, the first/third connecting pattern 171, 371, the first substrate 100, the second insulating pattern 250, the second/fourth connecting pattern 271, 471, and the second substrate 200 may be sequentially stacked on the package substrate 10.

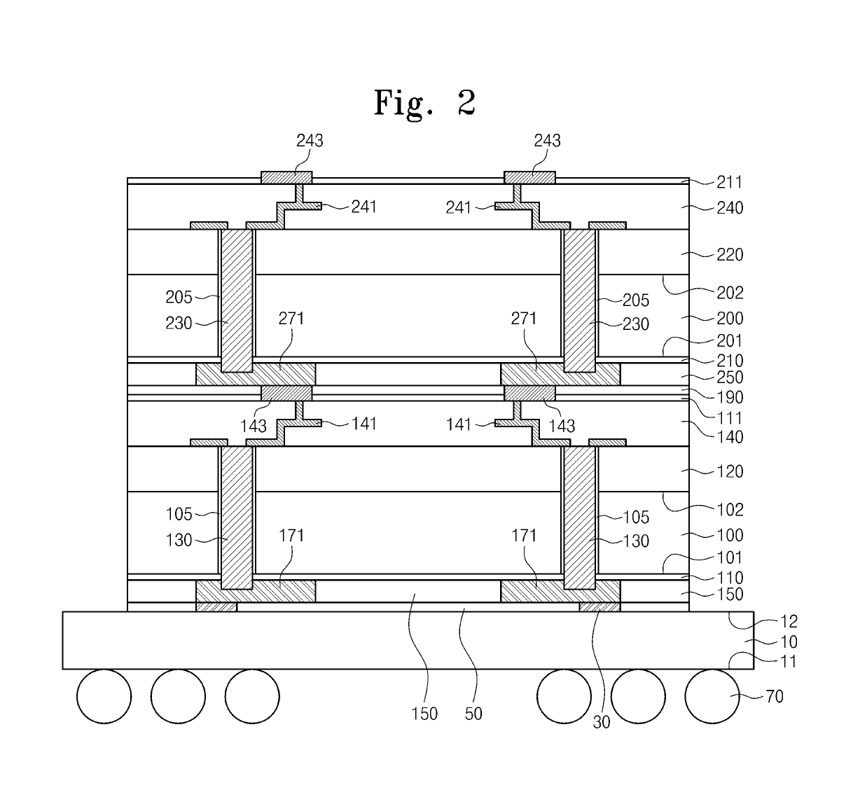

FIG. 2 is a sectional view of a semiconductor package according to other example embodiments of the inventive concepts.

Hereinafter, a semiconductor package according to other example embodiments of the inventive concepts will be described with reference to FIG. 2. For concise description, overlapping description of elements previously described with reference to FIG. 1A and FIG. 1B may be omitted.

Referring to FIG. 2, a semiconductor package may include a package substrate 10 with a first surface 11 and a second surface 12 facing each other. A first substrate 100 may be provided on the second surface 12 of the package substrate 10. A first interlayer dielectric 120 may be provided on the second surface 102 of the first substrate 100. A first through electrode 130 may penetrate the first substrate 100 and the first interlayer dielectric 120. A first liner layer 105 may be provided between the first through electrode 130 and the first substrate 100. The first liner layer 105 may extend between the first through electrode 130 and the first interlayer dielectric 120. The first interlayer dielectric 120 may include an integrated circuit and/or a metal interconnection line. The integrated circuit may include at least one of a random access memory (RAM) cell, a nonvolatile memory cell, a memory controller, an application processing circuit, a power supply circuit, a modem, or a radio frequency (RF) circuit. The integrated circuit and/or the metal interconnection line may be electrically connected to the first through electrode 130.

A second interlayer dielectric 140 may be provided on the first interlayer dielectric 120. The second interlayer dielectric 140 may include a first metal interconnection line 141. The first metal interconnection line 141 may be electrically connected to the first through electrode 130. A fifth metal pad 143 may be provided on the second interlayer dielectric 140. The fifth metal pad 143 may be electrically connected to the first metal interconnection line 141 of the second interlayer dielectric 140. A second insulating layer 111 may be provided on the second interlayer dielectric 140. The second insulating layer 111 may be formed to expose the fifth metal pad 143.

A second substrate 200 may be provided on the first substrate 100. A third interlayer dielectric 220 and a fourth interlayer dielectric 240 may be sequentially provided on the second substrate 200. The third and fourth interlayer dielectrics 220 and 240 may be configured to have substantially the same technical features as the first and second interlayer dielectrics 120 and 140. A sixth metal pad 243 may be provided on the fourth interlayer dielectric 240. The sixth metal pad 243 may be configured to have the substantially the same technical features as the fifth metal pad 143.

A second insulating pattern 250 may be provided between the first substrate 100 and the second substrate 200. The second insulating pattern 250 may be formed to partially expose the second interlayer dielectric 140 and the second substrate 200. The second insulating pattern 250 may be formed to expose a portion of a second through electrode 230 and at least a portion of the fifth metal pad 143. In addition, as described with reference to FIGS. 1A and 1B, a second adhesive layer 190 may be provided on the second insulating layer 111. The second adhesive layer 190 may be formed to expose a portion of the fifth metal pad 143.

A second connecting pattern 271 may be provided in a space defined by the second interlayer dielectric 140 of the first substrate 100, the second substrate 200, and the second insulating pattern 250. The second connecting pattern 271 may be configured to electrically connect the fifth metal pad 143 with the second through electrode 230. In some embodiments, a void may be formed between a first connecting pattern 171 and the elements defining the space.

In the semiconductor package, a first insulating pattern 150 and the first connecting pattern 171, the first substrate 100, the first interlayer dielectric 120, the second interlayer dielectric 140, the second insulating pattern 250 and the second connecting pattern 271, the second substrate 200, the third interlayer dielectric 220, and the fourth interlayer dielectric 240 may be sequentially stacked on the package substrate 10.

The package substrate 10, the first substrate 100, the second substrate 200, the first through electrode 130, the second through electrode 230, the first insulating pattern 150, and the second insulating pattern 250 may be configured to have substantially the same technical features as those, designated with the same reference number, of the example embodiments described with reference to FIGS. 1A and 1B.

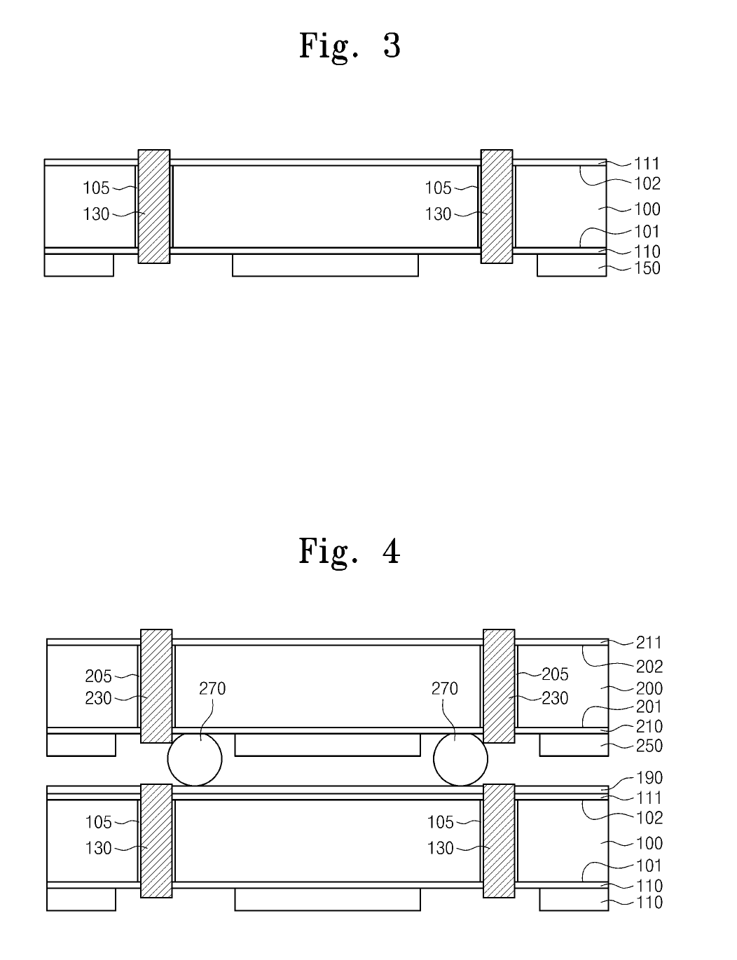

FIGS. 3 through 5 are sectional views illustrating a method of fabricating a semiconductor package according to example embodiments of the inventive concepts.

Hereinafter, methods of fabricating a semiconductor package according to example embodiments of the inventive concepts will be described with reference to FIG. 1A to FIG. 5.

Referring to FIG. 3, a first substrate 100 with a first surface 101 and a second surface 102 facing each other may be provided. The first substrate 100 may be formed of silicon (Si) or a semiconductor material containing silicon. The first substrate 100 may include an integrated circuit and/or a metal interconnection line. First and second insulating layers 110, 111 may be formed on the first and second surfaces 101 and 102 of the first substrate 100. A through hole may be formed to penetrate the first substrate 100 and the first and second insulating layers 110, 111. The formation of the through hole may be performed using a laser drilling process. A first liner layer 105 may be formed on a sidewall of the through hole. The first liner layer 105 may be formed of a silicon oxide layer or a silicon nitride layer. A first through electrode 130 may be formed by filling the through hole provided with the first liner layer 105 with a conductive layer. The first through electrode 130 may be formed of at least one of polysilicon, metal or any combination thereof, and one of a deposition process, an epitaxial growth process, or a plating process may be used to form the first through electrode 130. In some embodiments, the formation of the first through electrode 130 may include depositing a metal layer (e.g., of copper or tungsten) or a polysilicon layer, and then planarizing the metal or polysilicon layer to expose the insulating layer. The planarization process may be performed using one of an etch-back process, a back grinding process, or a chemical mechanical polishing (CMP) process. The formation of the first through electrode 130 may be performed in such a way that both ends of the first through electrode 130 are protruded from the first and second surfaces 101 and 102 of the first substrate 100, respectively.

In other embodiments, as shown in FIG. 2, a first interlayer dielectric 120 may be formed on the first substrate 100. The first through electrode 130 may be formed to penetrate the first interlayer dielectric 120 and the first substrate 100. A second interlayer dielectric 140 may be formed on the first substrate 100 provided with the first through electrode 130. A first metal interconnection line 141 may be formed in a second interlayer dielectric 140. A fifth metal pad 143 may be formed on the second interlayer dielectric 140. The fifth metal pad 143 may be electrically connected to a first metal interconnection line 141.

Referring again to FIG. 3, a first insulating pattern 150 may be formed on the first surface 101 of the first substrate 100. The first insulating pattern 150 may be formed to expose a portion of the first surface 101 and a portion of the first through electrode 130. The formation of the first insulating pattern 150 may include forming an insulating layer to cover the first surface 101 of the first substrate 100 and then patterning the insulating layer. In some embodiments, the first insulating pattern 150 may be formed of photosensitive polyimide (PSPI), and the formation thereof may include forming the PSPI layer on the first surface 101 of the first substrate 100 and then patterning the PSPI layer using a lithographic process.

A second adhesive layer 190 may be formed on the second surface 102 of the first substrate 100. The second adhesive layer 190 may be formed of at least one of insulating materials, such as an epoxy resin, a polyimide, or a permanent photoresist material. The second adhesive layer 190 may be formed to expose a portion of the first through electrode 130. Various methods may be used to form the second adhesive layer 190. In some embodiments, the second adhesive layer 190 may be formed by coating an adhesive layer in a spin coating manner. In other embodiments, the second adhesive layer 190 may be formed by coating an adhesive layer in a spraying manner. In still other embodiments, the second adhesive layer 190 may be formed by taping an adhesive film.

A second substrate 200 may be provided on the second surface 102 on the first substrate 100. The second substrate 200 may include a third surface 201 and a fourth surface 202 facing each other. Third and fourth insulating layers 210, 211 may be formed on the first surface 201 and the second surface 202 of the second substrate 200. The second substrate 200 may include a second liner layer 205 and a second through electrode 230, which may be configured like the first liner layer 105 and the first through electrode 130 of the first substrate 100.

In other embodiments, as shown in FIG. 2, a third interlayer dielectric 220 may be formed on the second substrate 200. The second through electrode 230 may be formed to penetrate the third interlayer dielectric 220 and the second substrate 200. A fourth interlayer dielectric 240 may be formed on the second substrate 200 provided with the second through electrode 230. The fourth interlayer dielectric 240 may include a second metal interconnection line 241. A sixth metal pad 243 may be formed on the fourth interlayer dielectric 240. The sixth metal pad 243 may be electrically connected to the second metal interconnection line 241.

A second insulating pattern 250 may be formed on the third surface 201 of the second substrate 200. The second insulating pattern 250 may be formed to expose at least a portion of the second through electrode 230.

As illustrated in FIG. 4, a second solder bump 270 may be formed in a region confined by the second insulating pattern 250. The second substrate 200 may be configured in such a way that the third surface 201 thereof faces the second surface 102 of the first substrate 100. A second adhesive layer 190 may be formed on the second surface 102 of the first substrate 100. The second solder bump 270 may be formed in a region surrounded by the second insulating pattern 250, the first substrate 100, and the second substrate 200. The second solder bump 270 may be formed to have a volume smaller than that of a space defined by the second insulating pattern 250, the first substrate 100, and the second substrate 200.

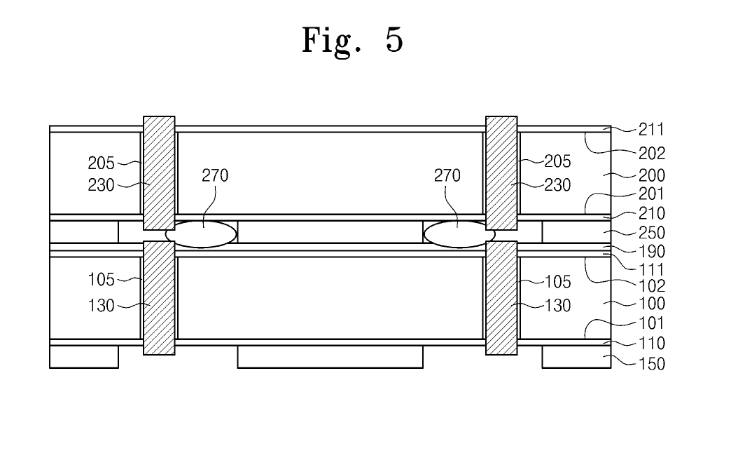

Referring to FIG. 05, the first substrate 100 and the second substrate 200 may be pressed against each other in such a way that the second adhesive layer 190 on the second surface 102 of the first substrate 100 may be in direct contact with the second insulating pattern 250 on the third surface 201 of the second substrate 200. As a result, the first and second substrates 100 and 200 may be adhered to each other and the second solder bump 270 therebetween may have a shape distorted from the original one depicted by FIG. 4.

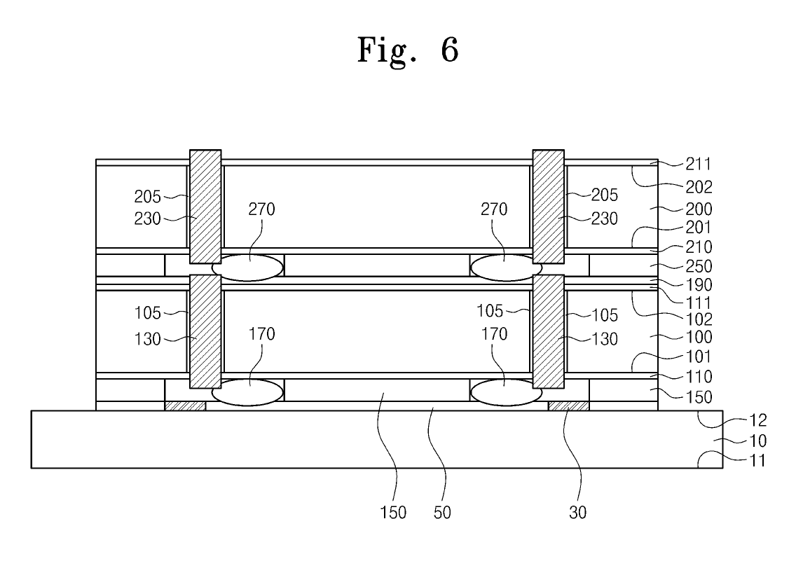

Referring to FIG. 6, a package substrate 10 may be provided. The package substrate 10 may include a first surface 11 and a second surface 12 facing each other. The package substrate 10 may include an integrated circuit and/or a metal interconnection line. A conductive pattern 30 may be formed on the second surface 12 of the package substrate 10. The conductive pattern 30 may be electrically connected to the integrated circuit and/or the metal interconnection line of the package substrate 10. The first substrate 100 and the second substrate 200 may be provided on the package substrate 10.

A first solder bump 170 may be formed in a space defined by the first insulating pattern 150. The space may be formed to expose a bottom end portion of the first through electrode 130. A first adhesive layer 50 may be formed between the package substrate 10 and the first substrate 100. The first adhesive layer 50 may be formed to expose the conductive pattern 30. The package substrate 10 and the first substrate 100 may be pressed against each other in such a way that the first adhesive layer 50 on the second surface 12 of the package substrate 10 may be in direct contact with the first insulating pattern 150 on the first surface 101 of the first substrate 100. As a result, the package substrate 10 and the first substrate 100 may be adhered to each other and the first solder bump 170 therebetween may have a shape distorted from the original one. The first solder bump 170 may be formed to have a volume smaller than that of the space exposed by the first insulating pattern 150.

Referring back to FIG. 1A, a thermal treatment may be performed on the resultant structure including the package substrate 10, and the first and second substrates 100 and 200 to form the first and second connecting patterns 171 and 271. The thermal treatment may be performed to melt the first and second solder bumps 170 and 270, and the first and second connecting patterns 171 and 271 may be obtained by cooling the first and second solder bumps 170 and 270 after melting. In some embodiments, the second connecting pattern 271 may be formed to fill a first space provided by the first substrate 100, the second substrate 200, and the second insulating pattern 250, and the first connecting pattern 171 may be formed to fill a second space provided by the first substrate 100, the package substrate 10 and the first insulating pattern 150. In other embodiments, as shown in FIG. 1B, the first and second spaces may not be fully filled with the third and fourth connecting patterns 371 and 471, respectively, and therefore, a void may be formed in at least one of the first and second spaces. The second through electrode 230 and the first through electrode 130 may be electrically connected with each other via the second/fourth connecting pattern 271,471 provided between the first substrate 100 and the second substrate 200. In addition, the first through electrode 130 and the conductive pattern 30 may be electrically connected with each other via the first/third connecting pattern 171, 371 provided between the first substrate 100 and the package substrate 10. A connecting terminal 70 may be formed on the first surface 11 of the package substrate 10. The connecting terminal 70 may be electrically connected to the integrated circuit and/or the metal interconnection line of the package substrate 10. The connecting terminal 70 may be formed to have a ball shape. For example, the connecting terminal 70 may be a solder ball.

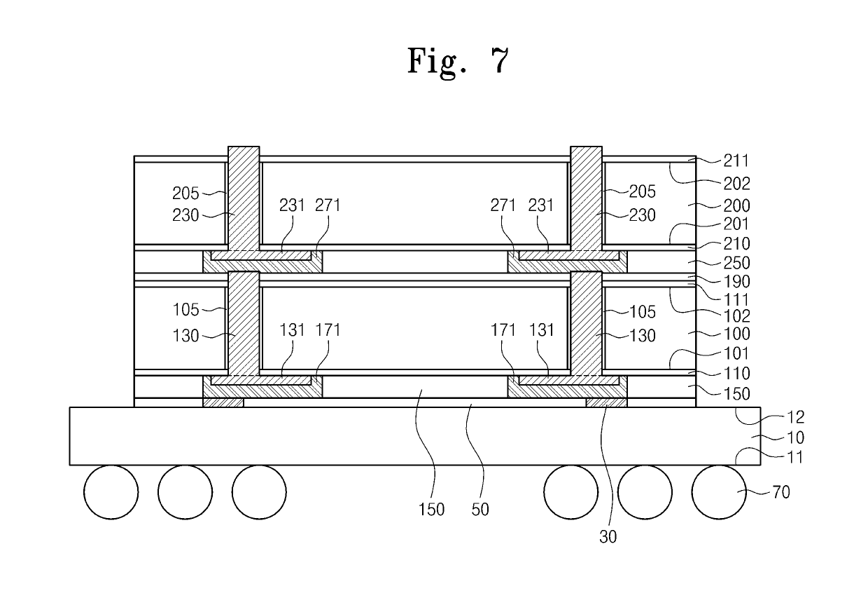

Hereinafter, semiconductor packages and methods of fabricating the same according to other example embodiments of the inventive concepts will be described with reference to FIGS. 7 through 10. For concise description, overlapping description of elements previously described with reference to FIGS. 1A through FIG. 6 may be omitted.

FIG. 7 is a sectional view illustrating a semiconductor package and a method of fabricating the same according to further example embodiments of the inventive concepts.

Referring to FIG. 7, a semiconductor package may include a first substrate 100 provided with a first through electrode 130, a first metal pad 131 disposed at one side of the first through electrode 130, a second substrate 200 provided with a second through electrode 230, a second metal pad 231 disposed at one side of the second through electrode 230, and a package substrate 10 provided with a conductive pattern 30.

The first substrate 100, the second substrate 200 and the package substrate 10 may be configured to have substantially the same technical features as those, designated with the same reference number, of the afore-described embodiments.

The first metal pad 131 may be connected to one side of the first through electrode 130 on a first surface 101 of the first substrate 100. In addition, the second metal pad 231 may be connected to one side of the first through electrode 130 on a third surface 201 of the second substrate 200. A first insulating pattern 150 may be disposed between the package substrate 10 and the first substrate 100 to expose the first metal pad 131. A first connecting pattern 171 may be provided in a space defined by the package substrate 10, the first substrate 100, and the first insulating pattern 150. The first connecting pattern 171 may be configured to electrically connect the first metal pad 131 with the conductive pattern 30. A second insulating pattern 250 may be disposed between the first substrate 100 and the second substrate 200 to expose the second metal pad 231 and the first through electrode 130. A second connecting pattern 271 may be provided in a space defined by the first substrate 100, the second substrate 200, and the second insulating pattern 250. The second connecting pattern 271 may be configured to electrically connect the second metal pad 231 with the first through electrode 130.

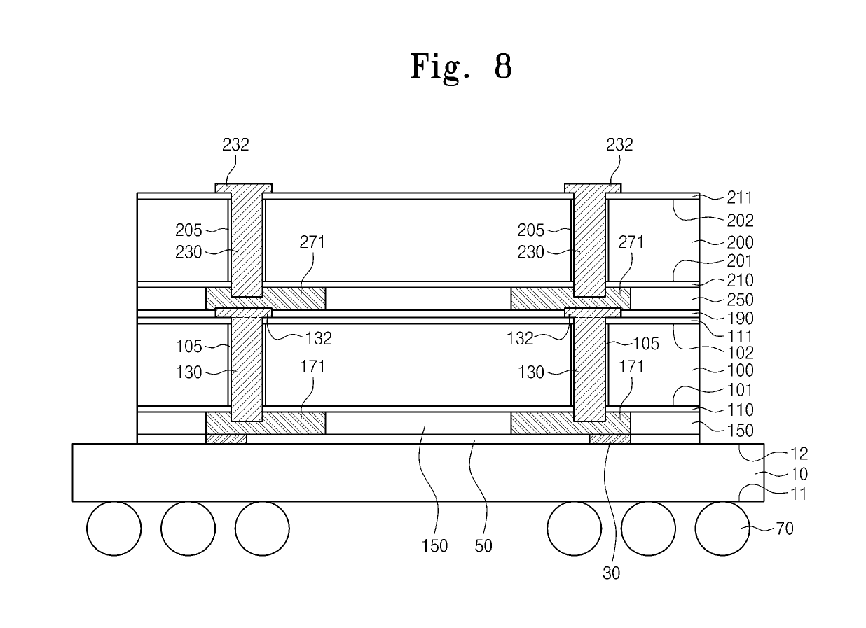

Hereinafter, methods of fabricating a semiconductor package according to still other example embodiments of the inventive concepts will be described with reference to FIG. 8.

A first substrate 100 provided with a first through electrode 130, a first metal pad 131 disposed at one side of the first through electrode 130, a second substrate 200 provided with a second through electrode 230, a second metal pad 231 disposed at one side of the second through electrode 230, and a package substrate 10 provided with a conductive pattern 30 may be provided.

The first substrate 100, the second substrate 200 and the package substrate 10 may be configured to have substantially the same technical features as those, designated with the same reference number, of the afore-described embodiments.

The first metal pad 131 may be formed on a first surface 101 of the first substrate 100 in such a way that the first metal pad 131 is connected to one side of the first through electrode 130. The first metal pad 131 may be electrically connected to the first through electrode 130. In addition, the second metal pad 231 may be formed on a third surface 201 of the second substrate 200 in such a way that the second metal pad 231 is connected to one side of the second through electrode 230. The second metal pad 231 may be electrically connected to the second through electrode 230. In other embodiments, the formation of the first metal pad 131 may include forming a through hole to penetrate the first substrate 100 and then forming a conductive layer to fill the through hole and cover the first surface 101 of the first substrate 100. The conductive layer may be formed of substantially the same material as that of the embodiments described with reference to FIG. 3. The first through electrode 130 and the first metal pad 131 may be simultaneously formed by patterning the conductive layer. In some embodiments, the first through electrode 130 and the first metal pad 131 may be simultaneously formed. The formation of the first through electrode 130 may be performed in such a way that one end of the first through electrode 130 is protruded from the second surface 102 of the first substrate 100. In addition, the formation of the second metal pad 231 may be performed in the same manner as that of the first metal pad 131.

A first insulating pattern 150 may be formed on the first surface 101 of the first substrate 100. As illustrated in FIG. 7, the first insulating pattern 150 may be formed between the package substrate 10 and the first substrate 100 to expose the first metal pad 131 and the conductive pattern 30. As shown in FIG. 6, a first solder bump may be formed in a space defined by the package substrate 10, the first substrate 100 and the first insulating pattern 150.

As shown in FIG. 7, a second insulating pattern 250 may be formed between the first substrate 100 and the second substrate 200 to expose the second metal pad 231 and the first through electrode 130. A second solder bump may be formed in a space defined by the first substrate 100, the second substrate 200 and the second insulating pattern 250. A thermal treatment may be performed on the resultant structure including the package substrate 10, and the first and second substrates 100 and 200 to form the first and second connecting patterns 171 and 271. The thermal treatment may be performed to melt the first and second solder bumps, and the first and second connecting patterns 171 and 271 may be obtained by cooling the melted first and second solder bumps. The first metal pad 131 and the conductive pattern 30 may be electrically connected to each other via the first connecting pattern 171, and the first through electrode 130 and the second metal pad 231 may be electrically connected to each other via the second connecting pattern 271.

After the formation of the first and second connecting patterns 171 and 271, a connecting terminal 70 may be formed on the first surface 11 of the package substrate 10. The connecting terminal 70 may be formed to have a ball shape. For example, the connecting terminal 70 may be a solder ball.

FIG. 8 is a sectional view illustrating a semiconductor package and a method of fabricating the same according to further example embodiments of the inventive concepts.

Referring to FIG. 8, a semiconductor package may include a first substrate 100 provided with a first through electrode 130, a third metal pad 132 disposed at one side of the first through electrode 130, a second substrate 200 provided with a second through electrode 230, a fourth metal pad 232 disposed at one side of the second through electrode 230, and a package substrate 10 provided with a conductive pattern 30.

The first substrate 100, the second substrate 200 and the package substrate 10 may be configured to have substantially the same technical features as those, designated with the same reference number, of the afore-described embodiments.

The third metal pad 132 may be connected to one side of the first through electrode 130 on a second surface 102 of the first substrate 100. In addition, the fourth metal pad 232 may be connected to one side of the second through electrode 230 on a fourth surface 202 of the second substrate 200. A first insulating pattern 150 may be disposed between the package substrate 10 and the first substrate 100 to expose the first through electrode 130. A first connecting pattern 171 may be provided in a space defined by the package substrate 10, the first substrate 100, and the first insulating pattern 150. The first connecting pattern 171 may be configured to electrically connect the first through electrode 130 with the conductive pattern 30. A second insulating pattern 250 may be disposed between the first substrate 100 and the second substrate 200 to expose the third metal pad 132 and the second through electrode 230. A second connecting pattern 271 may be provided in a space defined by the first substrate 100, the second substrate 200, and the second insulating pattern 250. The second connecting pattern 271 may be configured to electrically connect the third metal pad 132 with the second through electrode 230.

Hereinafter, methods of fabricating a semiconductor package according to other example embodiments of the inventive concepts will be described with reference to FIG. 8.

A first substrate 100 provided with a first through electrode 130, a third metal pad 132 disposed at one side of the first through electrode 130, a second substrate 200 provided with a second through electrode 230, a fourth metal pad 232 disposed at one side of the second through electrode 230, and a package substrate 10 provided with a conductive pattern 30 may be provided.

The first substrate 100, the second substrate 200 and the package substrate 10 may be configured to have substantially the same technical features as those, designated with the same reference number, of the afore-described embodiments.

A third metal pad 132 may be formed on a second surface 102 of the first substrate 100 in such a way that the third metal pad 132 is connected to one side of the first through electrode 130. The third metal pad 132 may be electrically connected to the first through electrode 130. In addition, a fourth metal pad 232 may be formed on a fourth surface 202 of the second substrate 200 in such a way that the fourth metal pad 232 is connected to one side of the second through electrode 230. In other embodiments, the formation of the third metal pad 132 may include forming a through hole to penetrate the first substrate 100 and then forming a conductive layer to fill the through hole and cover the second surface 102 of the first substrate 100. The conductive layer may be formed of substantially the same material as that of the embodiments described with reference to FIG. 2. The first through electrode 130 and the third metal pad 132 may be formed by patterning the conductive layer. In some embodiments, the first through electrode 130 and the third metal pad 132 may be simultaneously formed. The formation of the first through electrode 130 may be performed in such a way that one end of the first through electrode 130 is protruded from the first surface 101 of the first substrate 100. In addition, the formation of the fourth metal pad 232 may be performed in the same manner as that of the third metal pad 132.

A first insulating pattern 150 may be formed between the package substrate 10 and the first substrate 100 to expose the first through electrode 130 and the conductive pattern 30. As illustrated in FIG. 6, a first solder bump may be formed in a space defined by the package substrate 10, the first substrate 100 and the first insulating pattern 150.

A second insulating pattern 250 may be formed between the first substrate 100 and the second substrate 200 to expose the third metal pad 132 and the second through electrode 230. As illustrated in FIG. 6, a second solder bump may be formed in a space defined by the first substrate 100, the second substrate 200 and the second insulating pattern 250.

A thermal treatment may be performed on the resultant structure including the package substrate 10, and the first and second substrates 100 and 200 to form the first and second connecting patterns 171 and 271. The thermal treatment may be performed to melt the first and second solder bumps, and the first and second connecting patterns 171 and 271 may be obtained by cooling the melted first and second solder bumps. As illustrated in FIG. 8, the first through electrode 130 and the conductive pattern 30 may be electrically connected to each other via the first connecting pattern 171, and the second through electrode 230 and the third metal pad 132 may be electrically connected to each other via the second connecting pattern 271.

After the formation of the first and second connecting patterns 171 and 271, a connecting terminal 70 may be formed on the first surface 11 of the package substrate 10. The connecting terminal 70 may be formed to have a ball shape. For example, the connecting terminal 70 may be a solder ball.

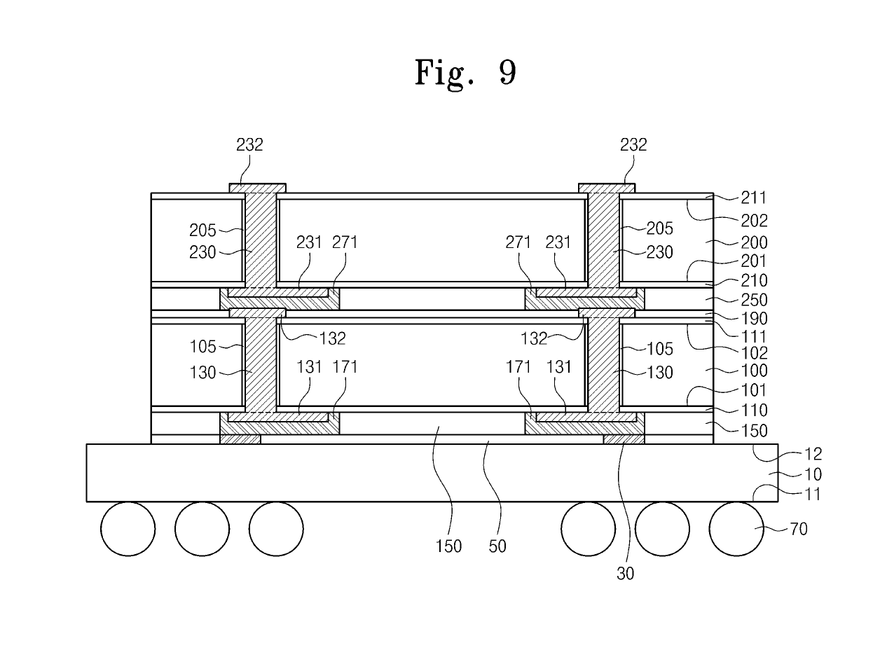

FIG. 9 is a sectional view illustrating a semiconductor package and a method of fabricating the same according to other example embodiments of the inventive concepts.

Referring to FIG. 9, a semiconductor package may include a first substrate 100 provided with a first through electrode 130, first and third metal pads 131 and 132 disposed at both sides, respectively, of the first through electrode 130, a second substrate 200 provided with a second through electrode 230, second and fourth metal pads 231 and 232 disposed at both sides, respectively, of the second through electrode 230, and a package substrate 10 provided with a conductive pattern 30.

The first substrate 100, the second substrate 200 and the package substrate 10 may be configured to have substantially the same technical features as those, designated with the same reference number, of the afore-described embodiments.

The first metal pad 131 may be connected to one side of the first through electrode 130 on a first surface 101 of the first substrate 100. In addition, the third metal pad 132 may be connected to the other side of the first through electrode 130 on a second surface 102 of the first substrate 100.

The second metal pad 231 may be connected to one side of the second through electrode 230 on a third surface 201 of the second substrate 200. In addition, the fourth metal pad 232 may be connected to the one side of the second through electrode 230 on a fourth surface 202 of the second substrate 200.

A first insulating pattern 150 may be disposed between the package substrate 10 and the first substrate 100 to expose the first metal pad 131 and the conductive pattern 30. A first connecting pattern 171 may be provided in a space defined by the package substrate 10, the first substrate 100, and the first insulating pattern 150. The first connecting pattern 171 may be configured to electrically connect the first metal pad 131 with the conductive pattern 30. A second insulating pattern 250 may be disposed between the first substrate 100 and the second substrate 200 to expose the second metal pad 231 and the third metal pad 132. A second connecting pattern 271 may be provided in a space defined by the first substrate 100, the second substrate 200, and the second insulating pattern 250. The second connecting pattern 271 may be configured to electrically connect the second metal pad 231 with the third metal pad 132.

Hereinafter, methods of fabricating a semiconductor package according to further example embodiments of the inventive concepts will be described with reference to FIG. 9.

A first substrate 100 provided with a first through electrode 130, a third metal pad 132 disposed at one side of the first through electrode 130, a second substrate 200 provided with a second through electrode 230, a fourth metal pad 232 disposed at one side of the second through electrode 230, and a package substrate 10 provided with a conductive pattern 30 may be provided.

The first substrate 100, the second substrate 200 and the package substrate 10 may be configured to have substantially the same technical features as those, designated with the same reference number, of the afore-described embodiments.

The first metal pad 131 may be connected to one side of the first through electrode 130 on a first surface 101 of the first substrate 100. In addition, a third metal pad 132 may be connected to the other side of the first through electrode 130 on a second surface 102 of the first substrate 100. As a result, the first and third metal pads 131 and 132 may be electrically connected to the first through electrode 130.

The second metal pad 231 may be connected to one side of the second through electrode 230 on a third surface 201 of the second substrate 200. In addition, the fourth metal pad 232 may be connected to the other side of the second through electrode 230 on a fourth surface 202 of the second substrate 200. As a result, the second and fourth metal pads 231 and 232 may be electrically connected to the second through electrode 230. In other embodiments, the formation of the first and third metal pads 131 and 132 may include forming a through hole to penetrate the first substrate 100 and then forming a conductive layer to fill the through hole and cover the first surface 101 of the first substrate 100. The conductive layer may be formed of substantially the same material as that of the embodiments described with reference to FIG. 3. The first through electrode 130 and the first metal pad 131 may be simultaneously formed by patterning the conductive layer. In addition, the formation of the third metal pad 132 may include forming a conductive layer on the second surface of the first substrate 100 and then patterning the conductive layer. The formation of the second through electrode 230, the second metal pad 231, and the fourth metal pad 232 may be performed in the same manner as those of the first through electrode 130, the first metal pad 131 and the third metal pad 132.

A first insulating pattern 150 may be formed between the package substrate 10 and the first substrate 100 to expose the first metal pad 131 and the conductive pattern 30. A first solder bump may be formed in a space defined by the package substrate 10, the first substrate 100 and the first insulating pattern 150.

A second insulating pattern 250 may be formed between the first substrate 100 and the second substrate 200 to expose the second metal pad 231 and the third metal pad 132. A second solder bump may be formed in a space defined by the first substrate 100, the second substrate 200 and the second insulating pattern 250.

A thermal treatment may be performed on the resultant structure including the package substrate 10, and the first and second substrates 100 and 200 to form the first and second connecting patterns 171 and 271. The thermal treatment may be performed to melt the first and second solder bumps, and the first and second connecting patterns 171 and 271 may be obtained by cooling the melted first and second solder bumps. The first metal pad 131 and the conductive pattern 30 may be electrically connected to each other via the first connecting pattern 171, and the second metal pad 231 and the third metal pad 132 may be electrically connected to each other via the second connecting pattern 271.

In some modified embodiments, positions of the insulating pattern and the adhesive layer may be variously changed, as will be described in below.

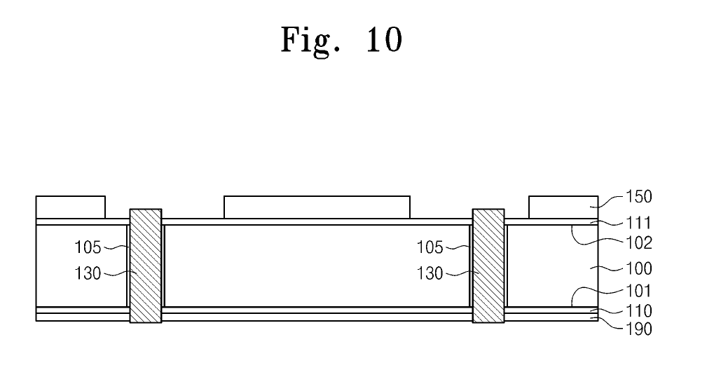

FIG. 10 is a sectional view illustrating a method of fabricating a semiconductor package according to further example embodiments of the inventive concepts.

Referring to FIG. 10, a first substrate 100 provided with a first through electrode 130, a second adhesive layer 190 on a first surface 101 of the first substrate 100, a first insulating pattern 150 on a second surface 102 of the first substrate 100, and a first solder bump (not illustrated) 170 may be provided.

The first substrate 100, the first electrode 130, the first solder bump 170 may be configured to have substantially the same technical features as those, designated with the same reference number, of the afore-described embodiments.

A second adhesive layer 190 may be formed on the first surface 101 of the first substrate 100. In addition, a first insulating pattern 150 may be formed on the second surface 102 of the first substrate 100. The first insulating pattern 150 may be formed to expose a portion of the first through electrode 130 and a portion of the second surface 102 of the first substrate 100. The first solder bump 170 may be formed in the space exposed by the first insulating pattern 150.

According to the described embodiments, spaces may be formed between the first, second and package substrates 100, 200 and 10 using the first and second insulating patterns 150 and 250 and then be filled with the first and second solder bumps 170 and 270. The first and second solder bumps 170 and 270 may be melted and then cooled to form the first and second connecting patterns 171 and 271 filling the spaces. The first and second through electrodes 130 and 230 and the conductive pattern 30, which may be disposed in or on the first, second and package substrates 100, 200 and 10, may be electrically connected to each other by using the first and second connecting patterns 171 and 271. As a result, it is possible to suppress misalignments among the first and second through electrodes 130 and 230 and the conductive pattern 30 during stacking the substrates 100, 200 and 10, and moreover, to reduce a device failure caused by the misalignment. Furthermore, it is possible to reduce the number of processes (i.e., process time) for fabricating the semiconductor package.

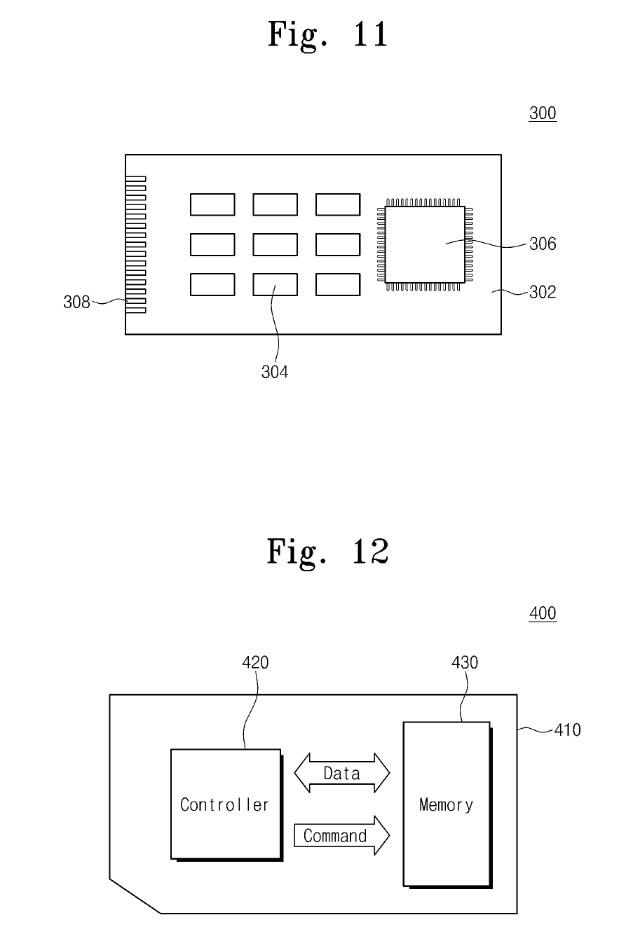

FIG. 11 is a schematic diagram of a semiconductor package module according to example embodiments of the inventive concepts.

Referring to FIG. 11, a semiconductor package module 300 may include a module substrate 302 provided with an input/output connecting terminal 308, a semiconductor chip 304, and a semiconductor package 306 mounted on the module substrate 302. In some embodiments, the semiconductor chip 304 may be configured to have substantially the same technical features as the first substrate 100. In addition, the semiconductor chip 304 and/or the semiconductor package 306 may be one of the semiconductor packages according to the afore-described example embodiments of the inventive concepts. The semiconductor package module 300 may be electrically connected to an external electronic device via the input/output connecting terminal 308.

FIG. 12 is a schematic diagram of a memory card according to example embodiments of the inventive concepts.

Referring to FIG. 12, a memory card 400 may include a controller 420 and a memory unit 430 provided in a housing 410. The controller 420 and the memory unit 430 may exchange electrical signals with each other. For example, the memory unit 430 and the controller 420 may transmit and receive data to/from each other according to a command of the controller 420. Accordingly, the memory card 400 may store data in the memory unit 430 or output data from the memory unit 430 to the outside.

In some embodiments, at least one of the controller 420 and the memory unit 430 may be one of the semiconductor devices or the semiconductor packages according to the afore-described example embodiments of the inventive concepts. The memory card 400 may be used as a data storage medium of various types of portable appliances. For example, the memory card 400 may include a multi-media card (MMC) or a secure digital (SD) card.

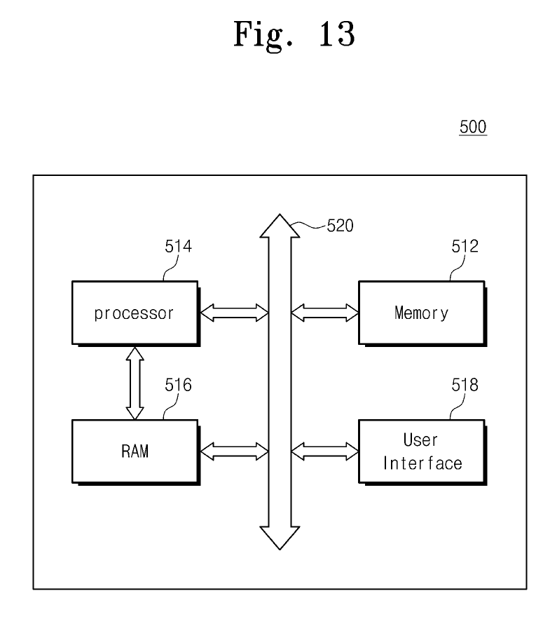

FIG. 13 is a block diagram of an electronic system according to example embodiments of the inventive concepts.

Referring to FIG. 13, an electronic system 500 may include one of the semiconductor devices or the semiconductor packages according to the afore-described example embodiments of the inventive concepts. The electronic system 500 may be, for example, a mobile device or a computer, and it may include at least one of a memory system 512, a processor 514, a RAM 516, and a user interface 518 that process data communication with one another via a bus 520. The processor 514 may execute programs and control the electronic system 500. The RAM 516 may be used as an operating memory of the processor the processor 514. In some embodiments, the processor 514 and the RAM 516 may be one of the semiconductor devices or the semiconductor packages according to the afore-described example embodiments of the inventive concepts. In other embodiments, the processor 514 and the RAM 516 may be included in the semiconductor package. The user interface 518 may be used to input or output data of the electronic system 500. The memory system 512 stores codes and data for operating the processor 514 or data inputted from the outside. The memory system 512 may include a controller and a memory unit. For instance, the memory system 512 may be configured to have substantially the same technical features as the memory card 400 of FIG. 12.

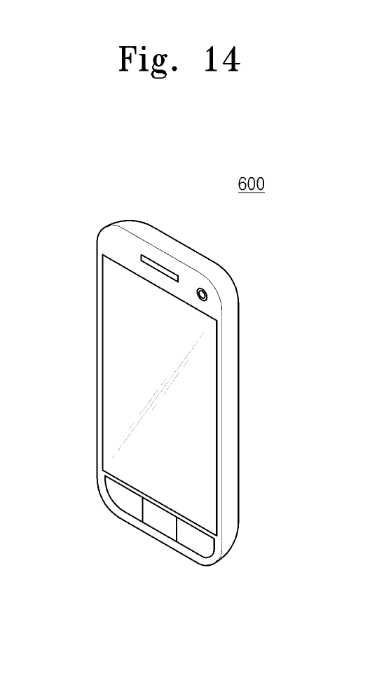

For example, the electronic system 500 may constitute various types of electronic controllers that require the memory unit of the memory system 512. For example, the electronic system 500 may be used in a mobile phone 600 as exemplarily shown in FIG. 14, an MP3 player, a navigation device, a solid state disk (SSD), or other household appliances.

According to example embodiments of the inventive concepts, even in the case that semiconductor substrates with through electrodes are not aligned to each other vertically, the through electrodes may be electrically connected with each other.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A semiconductor package, comprising:
a first substrate including a first surface and a second surface facing each other;
a first through electrode penetrating the first substrate;
a second substrate including a third surface and a fourth surface facing each other;
a second through electrode penetrating the second substrate;
an insulating pattern interposed between the second surface of the first substrate and the third surface of the second substrate to at least partially expose the second surface of the first substrate and the first surface of the second substrate; and
a connecting pattern disposed in a space defined by the insulating pattern and the first and second substrates to electrically connect the first through electrode with the second through electrode.

2. The semiconductor package of claim 1, further comprising a first metal pad disposed on the third surface of the second substrate and adjacent to the second through electrode, wherein the first and second through electrodes are electrically connected to each other via the first metal pad.

3. The semiconductor package of claim 1, further comprising a second metal pad disposed on the second surface of the first substrate and adjacent to the first through electrode, wherein the first and second through electrodes are electrically connected to each other via the second metal pad.

4. The semiconductor package of claim 1, further comprising:
a first interlayer dielectric on the second surface of the first substrate; and
a second interlayer dielectric on the first interlayer dielectric,
wherein the first through electrode penetrates the first interlayer dielectric to adjust a top surface of the first through electrode to be at least coplanar with a bottom surface of the second interlayer dielectric.

5. The semiconductor package of claim 4, further comprising a metal interconnection line disposed in the second interlayer dielectric to electrically connect the connecting pattern with the first through electrode.

6. The semiconductor package of claim 1, further comprising an adhesive layer on the second surface of the first substrate.

7. The semiconductor package of claim 6, further comprising an insulating layer on at least one of the third surface of the second substrate or the second surface of the first substrate.

8. The semiconductor package of claim 1, wherein the connecting pattern fills at least a portion of the space defined by the insulating pattern and the first and second substrates.

9. The semiconductor package of claim 8, further comprising:
a package substrate disposed to face the first surface of the first substrate;
a conductive pattern disposed on one surface of the package substrate; and
connecting terminals disposed on an opposite surface of the package substrate.

10. The semiconductor package of claim 8, wherein the connecting pattern and the connecting terminals are formed of a same material.

11-17. (canceled)

18. A semiconductor package, comprising:
a first substrate having a first through electrode penetrating opposing first and second surfaces of the first substrate;
a second substrate having a second through electrode penetrating opposing third and fourth surfaces of the second substrate;
an insulating pattern located between the second surface of the first substrate and the third surface of the second substrate, exposing at least part of the second surface of the first substrate and at least part of the third surface of the second substrate; and\an electrically connecting pattern in a space defined by the first substrate, the second substrate and the insulating pattern.

19. The semiconductor package of claim 18, further comprising a first metal pad located on the third surface of the second substrate and adjacent to the second through electrode, electrically connecting the first and the second through electrodes.

20. The semiconductor package of claim 18, further comprising a second metal pad located on the second surface of the first substrate and adjacent to the first through electrode, electrically connecting the first and the second through electrodes.

21. The semiconductor package of claim 18, further comprising:
a first interlayer dielectric on the second surface of the first substrate; and
a second interlayer dielectric on the first interlayer dielectric,
wherein the first through electrode penetrates the first interlayer dielectric to adjust a top surface of the first through electrode to be at least coplanar with a bottom surface of the second interlayer dielectric.

22. The semiconductor package of claim 21, further comprising a metal interconnection line located in the second interlayer dielectric, electrically connecting the connecting pattern with the first through electrode.

23-28. (canceled)
